(19) United States
(12) Patent Application Publication
(10) Pub. No.: US 2025/0083561 A1
(43) Pub. Date: Mar. 13, 2025

(54) LOW-VOLTAGE BATTERY DRAIN DETECTION SYSTEM FOR VEHICLES

(71) Applicant: GM GLOBAL TECHNOLOGY OPERATIONS LLC, Detroit, MI (US)

(72) Inventors: Joshua J. Sanchez, Melbourne, FL (US); Trupti R. KALE, Plymouth, MI (US); Carl J. HERING, Port Huron, MI (US); Ibnul Farabi KHAN, Berkley, MI (US); Philip Arthur DOOLEY, Royal Oak, MI (US); John HAASE, Shelby Township, MI (US)

(21) Appl. No.: 18/244,433

(22) Filed: Sep. 11, 2023

(51) Int. Cl. B60L 58/12; B60L 3/00; B60L 58/20

(52) U.S. Cl. CPC B60L 58/12; B60L 3/0046; B60L 58/20; B60L 2240/547

(57) ABSTRACT

A drain detection system for a vehicle includes: a sensor configured to detect parameters of a low-voltage battery of the vehicle and collect battery data including the parameters when the vehicle is OFF; a telematics module; and a control module configured to i) receive the battery data from the sensor when the vehicle is ON, ii) transmit via the telematics module the battery data to a network device, which is remotely located from the vehicle, iii) receive an alert message from the network device indicative of a parasitic drain on the low-voltage battery, and iv) perform a first countermeasure in response to the alert message.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to energy management systems of vehicles, and more particularly to drain detection systems for batteries of vehicles.

Traditional vehicles including internal combustion engines (ICEs) also include a low-voltage (e.g., a 12 V) battery. The low-voltage (LV) batteries are used for starting the ICEs and for powering various loads in the vehicles. The LV batteries are charged via alternators that convert mechanical energy from the ICEs to electrical energy to charge the LV batteries.

Electric vehicles, such as fully electric vehicles, battery electric vehicles (BEVs), and hybrid electric vehicles including plug-in hybrid electric vehicles (PHEVs), include high-voltage (HV) battery packs and LV batteries. A HV battery pack provides power to HV direct current (DC) loads and to an auxiliary power module that converts a high-voltage to a low-voltage to charge a low-voltage (LV) power source (or battery). The LV battery is used to power LV DC loads. The HV loads may include motors, which are used for propulsion purposes as well as other HV loads. The LV loads may include, for example, lights, window and seat motors, door locks, infotainment system devices, etc. A HV battery pack may have terminals at, for example, 400 V or 800 V. A LV battery may have terminals at, for example, 12V or 48V. A LV battery can be used to close a HV contactor when an electric vehicle is started to allow power from the HV battery pack to be supplied to motors and other HV loads.

### SUMMARY

A drain detection system for a vehicle is disclosed. The drain detection system includes: a sensor configured to detect parameters of a low-voltage battery of the vehicle and collect battery data including the parameters when the vehicle is OFF; a telematics module; and a control module configured to i) receive the battery data from the sensor when the vehicle is ON, ii) transmit via the telematics module the battery data to a network device, which is remotely located from the vehicle, iii) receive an alert message from the network device indicative of a parasitic drain on the low-voltage battery, and iv) perform a first countermeasure in response to the alert message.

In other features, the low-voltage battery is configured to close a contactor for a high-voltage battery pack or start an internal combustion engine.

In other features, the battery data includes a state of charge of the low-voltage battery. The state of charge is due to at least the parasitic drain. The alert message is generated based on the state of charge.

In other features, the battery data includes a drain rate of the low-voltage battery. The drain rate is due to at least the parasitic drain. The alert message is generated based on the drain rate.

In other features, the battery data includes a current draw of the low-voltage battery. The current draw is due to at least the parasitic drain. The alert message is generated based on the current draw.

In other features, the battery data indicates a low state of charge of a high-voltage battery pack of the vehicle. The alert message is generated based on the low state of charge of the high-voltage battery pack.

In other features, a drain detection system for a vehicle is disclosed. The drain detection system includes: a sensor configured to detect parameters of a low-voltage battery of the vehicle and collect battery data including the parameters when the vehicle is OFF; and a control module configured to i) receive the battery data from the sensor when the vehicle is ON, ii) based on the battery data, detect a parasitic drain on the low-voltage battery, and iii) perform a countermeasure in response to detecting the parasitic drain.

In other features, the low-voltage battery is configured to close a contactor for a high-voltage battery pack or start an internal combustion engine.

In other features, the battery data includes a state of charge of the low-voltage battery. The state of charge is due to at least the parasitic drain. The countermeasure is performed based on the state of charge.

In other features, the battery data includes a drain rate of the low-voltage battery. The drain rate is due to at least the parasitic drain. The countermeasure is performed based on the drain rate.

In other features, the battery data includes a current draw of the low-voltage battery. The current draw is due to at least the parasitic drain. The countermeasure is performed based on the current draw.

In other features, the battery data indicates a low state of charge of a high-voltage battery pack of the vehicle. The countermeasure is performed based on the low state of charge of the high-voltage battery pack.

In other features, a network device of a drain detection system for a first vehicle. The network device includes: a transceiver configured to receive battery data from the first vehicle, the battery data including parameters of a low-voltage battery of the first vehicle, and being collected when the first vehicle is OFF and transmitted to the network device when the first vehicle is ON; and a control module configured to detect a parasitic drain on the low-voltage battery based on the battery data, and in response to detecting the parasitic drain, transmit an alert message to the first vehicle indicative of the parasitic drain and to cause the first vehicle to perform a first countermeasure due to existence of the parasitic drain.

In other features, the transceiver is configured to receive battery data from multiple vehicles including the first vehicle, and transmit a second alert message to a second vehicle based on the battery data collected at the first vehicle.

In other features, the battery data indicates at least one of a state of charge of the low-voltage battery, a drain rate of the low-voltage battery, a current draw from the low-voltage battery, and a low state of charge of a high-voltage battery pack of the first vehicle. The control module is configured to perform the first countermeasure based on the at least one of the state of charge of the low-voltage battery, the drain rate of the low-voltage battery, the current draw from the low-voltage battery, and the low state of charge of the high-voltage battery pack.

In other features, the battery data indicates a state of charge of the low-voltage battery, a drain rate of the low-voltage battery, a current draw from the low-voltage battery, and a low state of charge of a high-voltage battery pack of the first vehicle. The control module is configured to perform the first countermeasure based on the state of charge of the low-voltage battery, the drain rate of the low-voltage battery, the current draw from the low-voltage battery, and the low state of charge of the high-voltage battery pack.

In other features, the control module is configured to: based on the battery data, determine that a first trigger condition is satisfied, which is indicative of existence of the parasitic drain; and in response to determining existence of the first trigger condition, perform the first countermeasure.

In other features, the control module is configured to: based on the battery data, determine that a second trigger condition is satisfied, which is indicative of existence of the parasitic drain, the second trigger condition being different than the first trigger condition; and in response to determining existence of the second trigger condition, perform a second countermeasure, the second countermeasure being different than the first countermeasure.

In other features, the control module is configured to: based on the battery data, determine that a third trigger condition is satisfied, which is indicative of existence of the parasitic drain, the third trigger condition being different than the first trigger condition and the second trigger condition; and in response to determining existence of the third trigger condition, perform a third countermeasure, the third countermeasure being different than the first countermeasure and the second countermeasure.

In other features, the control module is configured, based on the battery data, to determine that a first trigger condition and a second trigger condition are satisfied, which are indicative of the parasitic drain, and in response to determining existence of the first trigger condition and the second trigger condition, perform the first countermeasure.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example vehicle including at least a portion of a LV battery drain detection system in accordance with the present disclosure;

FIG. 2 is a functional block diagram of an example LV battery drain detection system including a back office and vehicles detecting and evaluating battery information collected while the vehicles are OFF in accordance with the present disclosure;

FIG. 3 illustrates an example battery data collection method in accordance with the present disclosure;

FIG. 4 illustrates a battery drain detection and responding method for a vehicle with an ICE in accordance with the present disclosure; and

FIG. 5 illustrates a battery drain detection and responding method for an electric vehicle in accordance with the present disclosure;

In the drawings, reference numbers may be reused to identify similar and/or identical elements.

### DETAILED DESCRIPTION

In an electric vehicle, a LV battery (e.g., 12 V, 24 V, or 48 V battery) can be used to power certain LV loads when the vehicle is OFF. For example, the LV battery can power an intelligent battery sensor (IBS) to allow the IBS to monitor the state of charge (SOC) of the LV battery. An IBS may be connected to a negative terminal of the LV battery and monitor current draw and voltage of the LV battery to, for example, determine when the LV battery should be recharged. If the SOC of the LV battery drops below a predetermined SOC, a no start condition can arise. A no start condition refers to when the vehicle is unable to start because the SOC of the LV battery is too low to close a HV contactor of a HV battery pack to charge the LV battery 108 and/or power HV loads.

As used herein, the SOC of a power source refers to a level of charge of the power source relative to a capacity of the power source. The SOC, for example, of a cell and/or battery pack module may refer to the voltage, current and/or amount of available energy stored in the cell and/or battery pack module. During operation, parameters such as voltage, current, and temperature of battery pack modules (or battery packs) and cells may be monitored to determine SOX values of the battery packs and cells. The acronym “SOX” refers to a state of charge (SOC), a state of health (SOH), state of power (SOP), and/or a state of function (SOF). The SOC of a cell and/or battery pack may refer to the voltage, current and/or amount of available power stored in the cell and/or battery pack. The SOH of a cell and/or battery pack may refer to: the age (or operating hours); whether there is a short circuit; whether there is a loose wire or bad connection; temperatures, voltages, power levels, and/or current levels supplied to or sourced from the cell and/or battery pack during certain operating conditions; and/or other parameters describing the health of the cell and/or battery pack. The SOF of a cell and/or battery pack may refer to a current temperature, voltage, and/or current level supplied to or sourced from the cell and/or battery pack, and/or other parameters describing a current functional state of the cell and/or battery pack.

A parasitic drain of a LV battery when a vehicle is OFF can result in the SOC of the LV battery to drop below a level where a no start condition exists. This can occur in both an electric vehicle and in a traditional vehicle having an ICE, in which case, the LV battery is unable to start the ICE. A parasitic drain refers to a drain (or load) on the LV battery when the vehicle is OFF (i.e., a HV contactor is open in an electric vehicle and an ICE is not running in a traditional vehicle). A parasitic drain is a load that is not a design intent load. When a vehicle is designed, certain loads (e.g., the IBS) are purposely designed to draw power when the vehicle is OFF. When current drawn from the LV battery increases beyond design intended loading for when the vehicle is OFF, the LV battery drains at a quicker rate than intended, which can result in a no start condition if the LV battery is not charged and/or the parasitic drain is not detected and resolved. Parasitic drains can cause rapid discharge of a LV battery and reduce life of the LV battery.

Proactive detection of a SOC of a LV battery and an alert indicating that the SOC of the LV battery is low focuses on the state of the LV battery and not on the cause of the low SOC of the LV battery.

The examples set forth herein include a LV battery drain detection system for detecting presence of parasitic drains, which can cause a LV battery to discharge. The LV battery drain detection system monitors parameters of the LV battery and evaluates whether certain conditions exist. Existence of the certain conditions are used as triggers to perform countermeasures, such as generation of alerts, performing selected vehicle operations, etc., which are further described below.

In some example embodiments, a cloud-based method is used to leverage information collected from a vehicle control module (e.g., a vehicle task manager) via a telematic control module (TCM) of a host vehicle. The information includes LV battery information, such as voltage, current draw, SOC, etc. The information is collected at a back office (or other central monitoring station) and evaluated external to the host vehicle. Alert messages are transmitted from the back office to the host vehicle such that the vehicle can than perform one or more countermeasures, as further described below. The back office may also use the collected information and evaluation results thereof for i) detecting issues at other vehicles, ii) evaluating data from other vehicles, and iii) alerting other vehicles and/or users thereof. The data collection and evaluation can occur during manufacturing of the host vehicle and post manufacturing of the host vehicle.

In other example embodiments, the vehicle control module of the host vehicle evaluates the information and performs countermeasures. This is done onboard the vehicle without external intervention. In other example embodiments, the information is shared externally and evaluated both at the back office and at the host vehicle. The back office provides alerts to the host vehicle, and the host vehicle, based on the alerts and onboard evaluation results, determines whether countermeasures should be performed and which countermeasures to perform.

As an example, the back office and/or a vehicle control module may process data collected onboard and generate one or more alerts to proactively identify existence of parasitic drains and the specific triggers associated with the detection. In this manner, the one or more triggers associated with the parasitic drains are isolated (i.e., identified). In a cloud-based system, vehicles with parasitic drains are identified and the collected information is used to determine which vehicles are experiencing the same issues, which aids in determining the cause(s) of the parasitic drains.

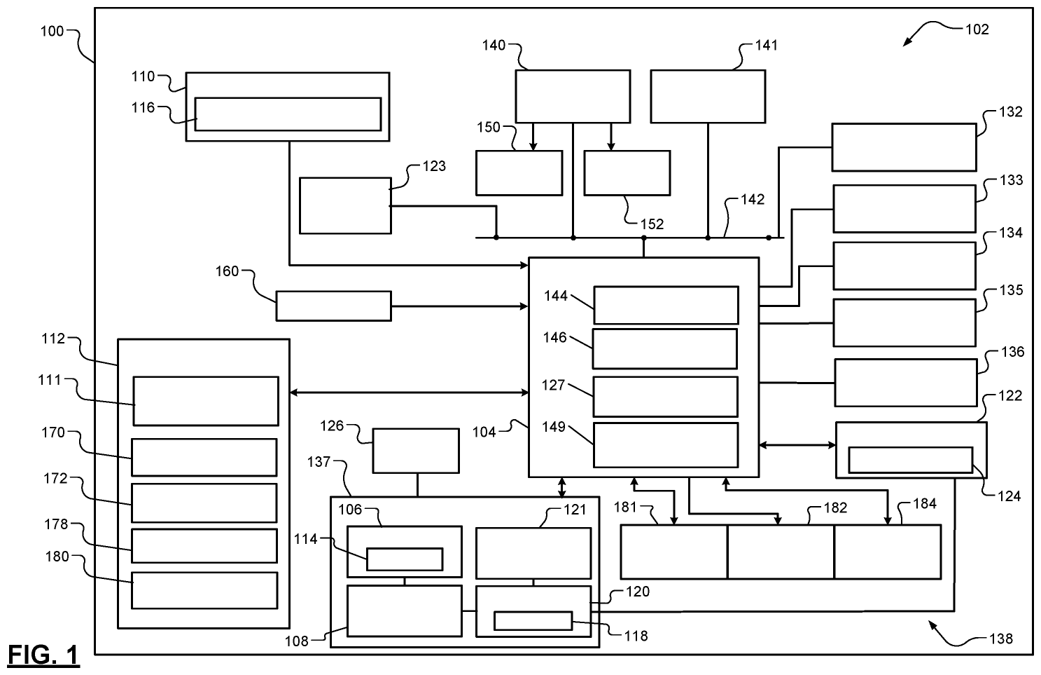

FIG. 1 shows a vehicle 100 including LV battery drain detection system 102 that collects LV battery information when the vehicle 100 is OFF. The vehicle 100 may be a traditional style vehicle with an ICE, an electric vehicle, or a hybrid vehicle. The LV battery information may be evaluated onboard and/or offboard the vehicle 100 to detect parasitic drains. The LV battery drain detection system 102 includes a vehicle control module 104, an IBS 106, a LV battery 108, and a telematics control module (TCM) 110, also referred to as a telematics module. The vehicle control module 104 monitors battery data collected from the IBS 106, which in an embodiment is connected to a negative terminal of the LV battery 108.

The battery data may include voltage data, current data, temperature data, etc. The voltage data and the current data indicating the voltage of the LV battery 108 and the current drawn from the LV battery 108. The temperature data indicating a temperature of the LV battery 108. The battery data may include the SOC of the LV battery 108. The battery data and other battery information, designated 111, may be stored in memory 112.

The IBS 106 is a smart sensor that includes logic for determining parameters of the LV battery 108 and memory 114 for storing the parameters and other battery data including raw battery data. The battery data stored in the memory 114 is transferred to the vehicle control module 104 when the vehicle 100 is tumed ON and the vehicle control module 104 is powered up. The IBS 106 detects the open circuit voltage (OCV) of the LV battery 108, current draw, temperatures, and/or other parameters of the LV battery 108. The IBS 106 may determine, based on these parameters, the capacity and/or SOC of the LV battery 108.

As a few examples, the LV battery 108 may be a 12V, 24V, or 48V battery. As referred to herein, a LV battery refers to a battery having a voltage of less than or equal to 96 V. The LV battery 108 may be used to close a contactor 118 of a control circuit 120 to supply power from a HV battery pack 121 to one or more HV loads 122, such as one or more motors 124. As referred to herein, a HV battery pack 121 refers to a battery pack having a voltage greater than or equal to 200 V. The contactor 118 is closed when the vehicle 100 is tumed ON. This may occur via an ignition switch 126 or remotely via a mobile access device, such as a key fob or a mobile phone that is in wireless communication with the vehicle control module 104.

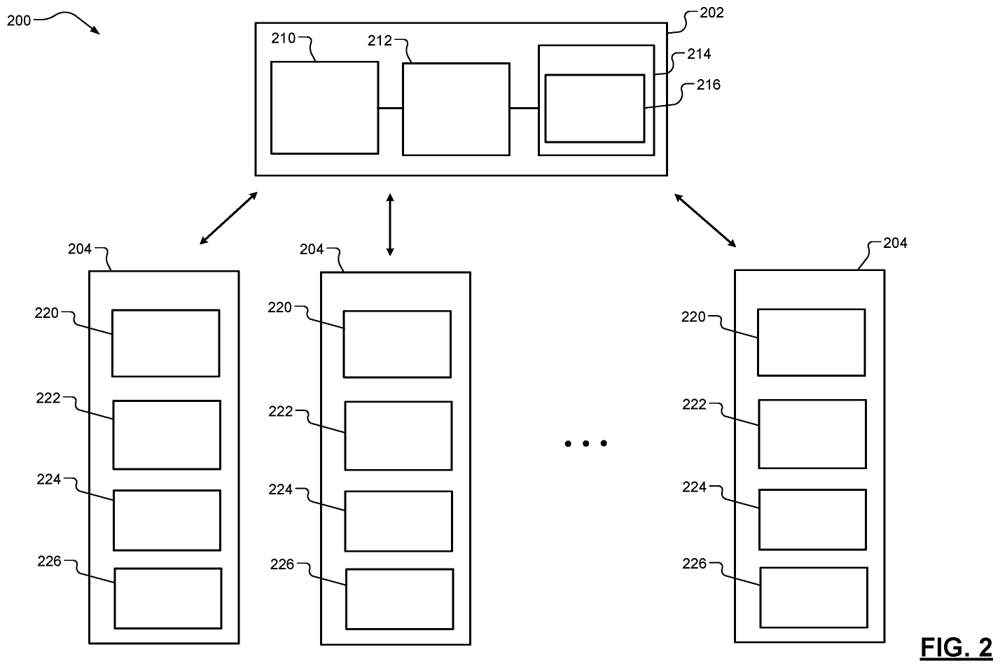

The vehicle control module 104 includes a LV drain detection module 127 that is configured to evaluate battery data received to determine whether certain trigger conditions exist. Examples of the trigger conditions are included in Table 1. In an embodiment, the vehicle control module 104 transmits battery data to a back office via the TCM 110. An example back office is shown in FIG. 2. The back office then evaluates the battery data and sends alert messages to the vehicle control module 104 when certain trigger conditions are satisfied, such as the trigger conditions in Table 1. The TCM 110 includes one or more transceivers 116 for remotely communicating with a back office.

The vehicle 100 may be a non-autonomous, partially autonomous or fully autonomous vehicle. The vehicle 100 may be a non-electric, hybrid or fully electric vehicle. The vehicle 100 further includes the steering system 132, a brake control system 133, a lighting system 134, a heating, ventilation and air conditioning system 135, accessories 136, the power sources 137 including the LV battery 108 and the HV battery pack 121, and a propulsion system 138. The vehicle 100 may further include an infotainment module 140 and other modules 141. The power sources 137 includes one or more battery packs (one HV battery pack 121 is shown) and the control circuit 120.

The sensors 123 may include various vehicle sensors, such as an accelerator sensor, a steering wheel sensor, a vehicle speed sensor, a brake actuator sensor, one or more accelerometers, and other sensors. The steering system 132 may include one or more front wheel steering actuators and one or more rear wheel steering actuators. The front wheel steering actuators turn the front wheels of the vehicle 100 and the rear wheel steering actuators turn the rear wheels of the vehicle 100.

The modules 104, 110, 140, 141 may communicate with each other and have access to the memory 114 via one or more buses and/or network interfaces. An example network interface (or bus) 142 is shown. The network interface (or bus) 142 may include a controller area network (CAN) bus, a local interconnect network (LIN) bus, an auto network communication protocol bus, and/or other network bus.

The vehicle control module 104 controls operation of vehicle systems. The vehicle control module 104 may include a mode selection module 144, a parameter adjustment module 146, the LV drain detection module 127, and a countermeasure module 149. The mode selection module 144 may select a vehicle operating mode, such as any of the modes referred to herein including ON, OFF and sleep modes, as well as other modes, such as driving modes, autonomous or partially autonomous modes, etc. The parameter adjustment module 146 may be used to adjust obtain and/or determine parameters of the vehicle 100 based on, for example, signals from the sensors 123 and/or other devices and modules referred to herein.

The vehicle 100 may further include a display 150 and an audio system 152, which may be used to provide alerts to a user and/or driver of the vehicle 100. The display 150 and/or audio system 152 may be implemented along with the infotainment module 140 as part of an infotainment system. The display 150 and/or other interface may be used to select an operating mode. This allows a user to set the operating modes of the vehicle 100. The display 150 and/or audio system 152 may also be used to indicate status messages. A message may be generated indicating the operating mode and/or when, for example, one or more certain trigger conditions have been satisfied. A message may be generated to indicate that the vehicle 100 should be plugged into a charging station to charge the HV battery pack 121. HV battery packs of electric vehicles are charged by connecting the electric vehicles to offboard charging stations. During a charge event, charge complete targets are met for a specific SOC (e.g., 96%).

A message may be generated when a SOC of the LV battery 108 is below a threshold and indicate that the vehicle 100 should be started to charge the LV battery 108. This may occur, for example, when there is an issue with the control circuit 120 and/or the vehicle control module 104 such that the control circuit 120 is not automatically charging the LV battery 108 via the HV battery pack 121 when the SOC of the LV battery is below a threshold for automatic charging. Various other messages may be generated, some of which are described below.

The vehicle 100 may further include a global positioning system (GPS) receiver 160. The GPS receiver 160 may provide vehicle velocity and/or direction (or heading) of the vehicle and/or global clock timing information. The GPS receiver 160 may also provide vehicle location information.

The memory 114 may store the battery data and information 111, tables 170, sensor data 172, vehicle parameters 178, and applications 180. The tables 170 may include relationships between parameters, such as relationships between open circuit voltages (OCVs), temperatures of the LV battery 108, and SOCs of the LV battery 108. A look-up table may be used to determine a SOC of the LV battery 108 based on a detected OCV and a temperature of the LV battery 108. The sensor data 172 includes data collected from the sensors 123. The vehicle parameters 178 may include parameters to be set and/or current states of parameters of the vehicle 100.

The applications 180 may include applications executed by the modules 104, 140, 141. Although the memory 114 and the vehicle control module 104 are shown as separate devices, the memory 114 and the vehicle control module 104 may be implemented as a single device. The memory 114 may be accessible to the LV drain detection module 127 and/or the countermeasure module 149.

The vehicle control module 104 may control operation of the systems 132, 133, 134, 135, the accessories 136, an engine 181, a converter/generator 182, a transmission 184, and/or the electric motors 124 according to parameters set by the modules 104, 140, 141. The vehicle control module 104 may set some of the vehicle parameters 178 based on signals received from the sensors 123.

The vehicle control module 104 may receive power from the power sources 137, which may be provided to the systems 132, 133, 134, 135, the accessories 136, the engine 181, the converter/generator 182, the transmission 184, and/or the electric motors 124, etc. Some of the vehicle control operations may include enabling fuel and spark of the engine 181, starting and running the electric motors 124, powering any of the systems 132, 133, 134, 135, and/or performing other operations as are further described herein.

The steering system 132, the brake control system 133, the engine 181, the converter/generator 182, the transmission 184, and/or the electric motors 124 may include actuators controlled by the vehicle control module 104 to, for example, adjust fuel, spark, air flow, steering wheel angle, throttle position, pedal position, motor torque, etc. This control may be based on the outputs of the sensors 123, the GPS receiver 160, and the above-stated data and information stored in the memory 114.

The vehicle control module 104 may determine various parameters including a vehicle speed, an engine speed, steering wheel angle, yaw rate of the vehicle 100, lateral acceleration of the vehicle 100, accelerator position, brake actuator position, an engine torque, a gear state, an accelerometer position, a brake pedal position, an amount of regenerative (charge) power, whether diagnostic trouble codes are set, and/or other information. This information may be determined by and/or shared with the modules 104, 110.

FIG. 2 shows a LV battery drain detection system 200 including a back office network device 202 (referred to as back office 202) and vehicles 204 detecting and evaluating battery information collected while the vehicles 204 are OFF. Each of the vehicles 204 may be implemented the same or similarly as the vehicle 100 of FIG. 1. The back office 202 may include a transceiver 210, a control module 212, and a memory 214 including one or more databases 216. The databases 216 may store vehicle information, such as model numbers, vehicle identification numbers (VINs), years, etc. The databases 216 may also store the battery data and information collected from the vehicles 204. The control module 212 may evaluate the vehicle information and send alert messages to one or more of the vehicles 204 when, for example, one or more of the trigger conditions referred to herein are satisfied by one or more of the vehicles 204. Trigger conditions may be satisfied at a first vehicle, and alert messages may be sent to other vehicles based on the satisfied conditions at the first vehicle.

The vehicles 204 may include TCMs (or telematics modules) 220, vehicle control modules 222, other loads 224, and power sources 226. The TCMs 220 communicate wirelessly with the transceiver 210. The vehicle control modules 222 are configured and operate similarly as the vehicle control module 104 of FIG. 1. The other loads 224 may refer to any of the loads shown and described with respect to FIG. 1, which may also be included on the vehicles 204 and/or other loads. The power sources 226 may include LV batteries, IBSs, HV battery packs, and control circuits.

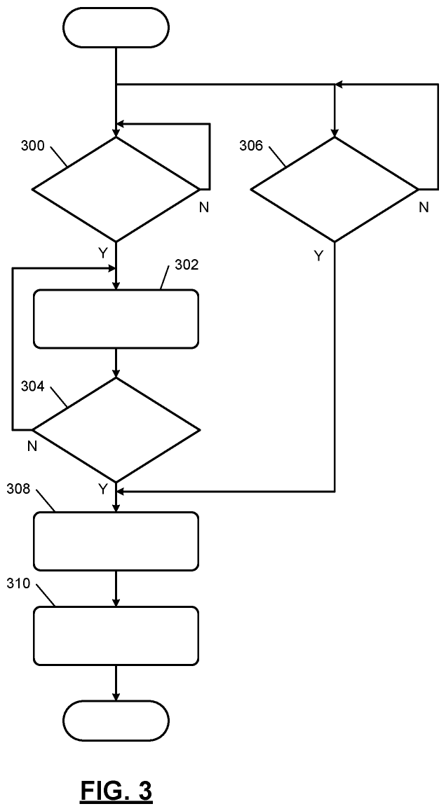

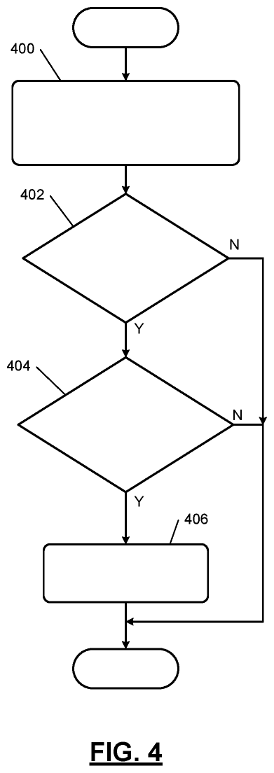

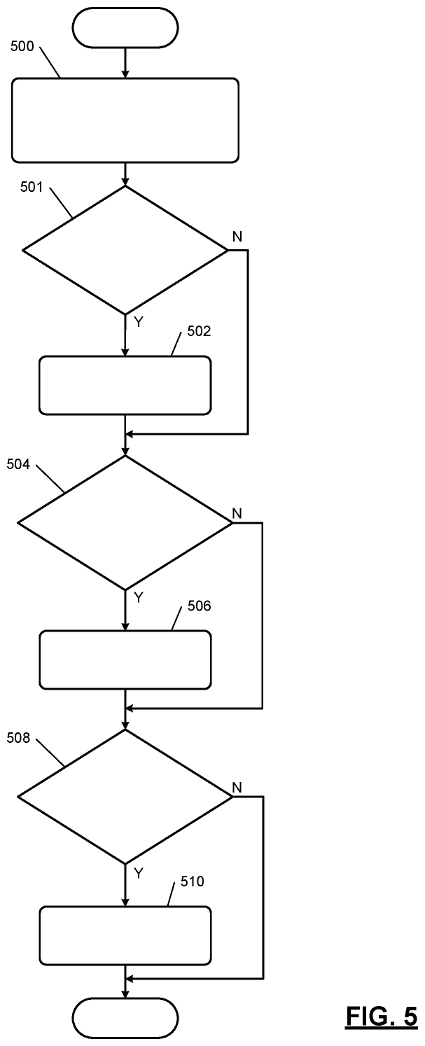

Although the following FIGS. 3-5 are shown as illustrating distinct methods, two or more of the methods may be performed together as a single method. The method of FIG. 3 may be performed prior to performing the methods of FIGS. 4-5. In an embodiment, FIG. 4 is performed for a vehicle having an ICE and FIG. 5 is performed for a vehicle having an electric motor.

FIG. 3 shows a battery data collection method. The following operations may be iteratively performed. Although the following operations are primarily described with respect to FIG. 1, the operations are applicable to other embodiments of the present disclosure.

At 300, the LV drain detection module 127 determines whether the network bus 142 is to wake up. This may be determined based on, for example, a schedule of the vehicle control module 104 to wake up and perform predetermined operations. The network bus 142 is up (or active) when there is traffic on the network bus 142. This occurs when the vehicle control module 104 is up (or ON) and transmitting data to and/or receiving data from one or more devices of the vehicle 100. The vehicle control module 104 may wakeup when a signal is received by the vehicle via, for example, the TCM 110. If the network bus 142 is up (or active), then operation 302 is performed.

At 302, the LV drain detection module 127 is configured to determine a SOC of the LV battery 108. This may be provided by the IBS 106.

At 304, the LV drain detection module 127 is configured to determine whether the SOC of the LV battery 108 is less than a threshold (e.g., 5-20%). If yes, operation 308 may be performed, otherwise operation 302 is performed.

At 306, the LV drain detection module 127 is configured to determine whether a periodic period has passed since a last collection of battery data for the LV battery 108. If yes, operation 308 is performed. The vehicle control module 104 is periodically waken up and performs predetermined operations, such as collecting battery data from the IBS 106.

At 308, the LV drain detection module 127 is configured to collect the battery data from the IBS 106 and/or the memory 114. The battery data may include voltage, current, and temperature data, as well as whether one or more trigger conditions have been satisfied, such as any of the trigger conditions in Table 1. At 310, the LV drain detection module 127 transmits via the TCM 110 the collected battery data. The battery data may be transmitted to the back office 202.

Some examples of the battery data collected and/or generated by the IBS 106 are included in Table 1. Table 1 includes some example trigger conditions, which are part of a rules-based logic. The examples include trigger names, descriptions of the corresponding trigger conditions, and logic used to detect when one or more of the trigger conditions are satisfied. In Table 1 X1-X9, Y1-Y5, and Z are thresholds. Table 1 may be used when performing the operations of the following FIGS. 4-5. Table 2 includes example ranges and values for each of the thresholds X1-X9, Y1-Y5, and Z. Other ranges and values may be implemented.

TABLE 1
Drain Detection Triggers

| Trigger Name | Description | Logic |
|---|---|---|
| Battery Saver Mode | Drain > X1 mA and/or | If True, operate in a |
| (BSM) | Voltage < Y1 V | Selected BSM, such as |
| | | BSM 1, BSM 2 . . . BSM 7 |
| Asleep Drain Rate (ADR) | Net Amp Hours | ADR > X2 more than Y2% |
| | Discharged Between | of time (or number of data |
| | Ignition OFF and ON | sample points) |
| | (asleep cycle) > X2 Amp | |
| | Hours | |
| Low State of Charge | LV Battery SOC Depleted | SOC of LV (e.g., 12 V) |
| (SOC) | | Battery < X3% |
| IBS Sensor Not Learning | IBS Not Able to Relearn | Regulated Voltage Control |
| | LV Battery SOC Due to | (RVC) SOC = X5 % for |
| | Current Drain > X4 mA | more than Y3% of time |
| | (e.g., 250 mA) | (or number of data sample |
| | | points) |
| Battery Current Histogram | IBS Measures Asleep | X6 Consecutive Unique |
| (BCH) | Current and Buckets | Instances of BCH (or |
| | Asleep Current | asleep current) > Y4 from |
| | Measurements to Provide | any Bucket > Z1-Z2 mA |
| | Histogram Including | |
| | Respective Bars Ranging | |
| | in Current Levels Between | |
| | 0-10 A | |
| SOC Error | SOC Error Increases | SOC Error > X7% |
| | When IBS is Not Able to | |
| | Relearn the LV Battery | |
| Cliff Edge | SOC Drops by at Least | MAX SOC Over Past n |
| | X8% over Past Y5 Hours | Hours-Current SOC > X8% |
| Low HV SOC | Enhanced Battery Support | HV SOC < X9% |
| | Mode (EBSM) Disabled | |
| | When HV SOC < X9% | |

TABLE 2
Example Thresholds and Values

| | Example Sample Threshold |
|---|---|
| Threshold | Range(s) and Value(s) |
| X1 | X1 ≤ 50-100 mA |
| X2 | X2 ≥ 0.1-1.0 Amp Hours |
| X3 | X3 ≤ 20% |
| X4 | X4 ≤ 50-250 mA, X4 ≤ 250 mA |
| X5 | X5 ≤ 90%, X5 = 65% |
| X6 | X6 ≥ 3-10 |
| X7 | X7 ≥ 5-10% |
| X8 | X8 ≥ 1-5% |
| X9 | X9 ≤ 10-20% |
| Y1 | Y1 ≤ 95% of a Normal Full |
| | Charge Voltage |
| Y2 | Y2 = 5-10% |
| Y3 | Y3 ≥ 10% |
| Y4 | Y4 ≥ 50-250 mA, Y4 ≥ 250 mA |
| Y5 | 5-10 hours, 8 hours |
| Z1 | Z1 ≥ 50 mA |
| Z2 | Z2 ≥ 250 mA |

In BSM 1, a first set operations are not permitted and/or limited. In BSM 2, a second set of operations are not permitted and/or limited. The second set of operations may include and/or be different than the first set of operations. This may be true for each of the BSM modes. As an example, in BSM 5, it may be determined whether the current drain of the LV battery 108 is greater than 500 mA. As another example, in BSM 7, it may be determined whether the voltage across the positive and negative terminals of the LV battery 108 is less than 11 V.

The ASD trigger condition is used to determine whether there is excessive net amp hours discharged between ignition OFF and ignition ON (an asleep cycle), where ASD is X2 more than Y2% of time (or predetermined number of data sample points). The trigger condition of when the IBS sensor is not learning may occur when the IBS 106 is not able to relearn the LV battery SOC due to the current drain being greater than X4 mA (e.g., 250 mA) and/or the RVC SOC being equal to X5% for more than Y3% of time (or number of data sample points). The IBS 106 operates based on an OCV of the LV battery 108 when the vehicle 100 is turned OFF. As an example, the IBS 106 may wait a predetermined period of time (e.g., 3 hours) after the vehicle 100 is shut off for the voltage of the LV battery 108 to settle and be at a steady-state voltage. The IBS 106 then measures the OCV and temperature of the LV battery 108 while at the steady-state voltage, and determines the SOC of the LV battery 108 based on the OCV and the temperature.

The BCH is a histogram having bars with respective sleep current levels and numbers of instances and/or periods of time that the sleep current drain of the LV battery 108 is at the sleep current levels of the bars. When there are X6 consecutive unique instances of BCH (or asleep current) greater than Y4 from any bucket greater than Z1-Z2 mA, then the BCH flag is set HIGH. The SOC error increases when the IBS 106 is not able to relearn the LV battery 108 due to the drain current being greater than X4 mA. The SOC error is related to whether the IBS 106 is able to releam the LV battery 108. If the IBS 106 is not able to learn because there is a parasitic drain present, then the SOC error increases as time goes by because the IBS is losing confidence in the current estimated SOC of the LV battery 108. When the SOC error is greater the X7% then the SOC error flag is set HIGH. The low HV SOC is set HIGH and the enhanced battery support mode is disabled when the HV SOC of the HV battery pack 121 is less than a predetermined EBSM threshold (or HV SOC %). The EBSM mode refers to when the HV battery pack 121 is charging the LV battery 108.

In an embodiment, the vehicle control module 104 is configured to send battery data (e.g., diagnostic data), including states of the trigger condition flags, periodically (e.g., daily) to the back office 202 and/or any time the network bus 142 has activity when the vehicle is OFF (referred to as the OFF power mode). In an embodiment, the battery diagnostic data is sent when the SOC of the LV battery flag is HIGH. This is done to prevent and/or minimize additional drain on the LV battery 108 while in the OFF power mode. This enables collecting battery data when the vehicle control module and/or one or more other modules and devices are transmitting data over the network bus 142. The network bus activity may be driven by the vehicle control module 104 and/or one or more other modules and devices and/or by a user. The battery data may be sent back to the back office 202 during active battery drain periods for early detections of parasitic drains and, in an embodiment, to identify an ECU (or processor) causing the parasitic drain. This identification is based on the one or more trigger conditions satisfied and may be determined using a stored look-up-table relating parasitic drains, trigger conditions, and vehicle processors.

FIG. 4 shows a battery drain detection and responding method for a vehicle with an ICE. This method may be performed onboard a vehicle (e.g., the vehicle 100 of FIG. 1 or any of the vehicles 204 of FIG. 2) or offboard at, for example, the back office 202 of FIG. 2. Some or all of the operations may be performed by the any of the modules 104, 212, 222 and are represented in the following operations by “the control module”. Any generated alert messages may be transmitted from the back office 202 to the vehicle 100 and/or be generated at the vehicle 100 and indicated via, for example, the display 150, the audio system 152, and/or other alerting device.

At 400, the control module and/or LV drain detection module 127 is configured to determine parameters and/or collect battery data of the LV battery 108. The battery data may include voltages, current levels, temperatures of the LV battery 108 and/or whether any the trigger conditions have been satisfied. This may be provided by the IBS 106 and/or may be provided using the method of FIG. 3.

At 402, the control module and/or LV drain detection module 127 is configured to determine whether one or more first trigger conditions are satisfied. When a trigger condition is satisfied, a corresponding flag is set to 1 in memory, otherwise the corresponding flag for that trigger condition remains 0. If yes, operation 404 may be performed, otherwise the method may end. As an example, an example first trigger condition may be whether the battery current histogram (BCH) is indicative that there has been X6 consecutive unique instances when the current draw has been greater than Z mA (e.g., 50-150 mA).

At 404, the control module and/or LV drain detection module 127 is configured to determine whether one or more second trigger conditions are satisfied. If yes, operation 406 may be performed, otherwise the method may end. As an example, the second trigger condition may include determining whether the low SOC flag is set to 1 and whether the ADR flag is set to 1. If yes, operation 406 is performed, otherwise the method may end.

At 406, the control module and/or the countermeasure module 149 may perform one or more countermeasures. This may include: generating one or more alert messages; automatically transitioning to charging the LV battery 108; automatically transitioning to charging the HV battery pack 121; autonomously starting the vehicle 100 to charge the LV battery 108; starting (if not already started) and driving the vehicle 100 to a service station; limiting loading on the LV battery 108, etc. The alert messages may include an indication to: start the vehicle 100 to charge the LV battery 108; drive the vehicle 100 to a service station; make an appointment for the vehicle 100 to be checked; alert driver or user of the vehicle 100 that a slow drain of the LV battery 108 exists; plug in the vehicle 100 to charge the HV battery pack 121; etc. The countermeasures may include storing information regarding the satisfied trigger condition, such as the name of the trigger condition, time and duration of occurrence, vehicle identification number, etc. for future use with regards to the vehicle 100 and/or other vehicles.

Numerous different combinations of the trigger conditions may be implemented for operations 402 and/or 406. Use of combinations of trigger conditions can prevent and/or minimize the number of false positives and false negatives.

FIG. 5 shows a battery drain detection and responding method for an electric vehicle. This method may be performed onboard a vehicle (e.g., the vehicle 100 of FIG. 1 or any of the vehicles 204 of FIG. 2) or offboard at, for example, the back office 202 of FIG. 2. Some or all of the operations may be performed by the any of the modules 104, 212, 222 and are represented in the following operations by “the control module”. Any generated alert messages may be transmitted from the back office 202 to the vehicle 100 and/or be generated at the vehicle 100 and indicated via, for example, the display 150, the audio system 152, and/or other alerting device.

At 500, the control module and/or the LV drain detection module 127 is configured to determine parameters and/or collect battery data of the LV battery 108. The battery data may include voltages, current levels, temperatures of the LV battery 108 and/or whether any the trigger conditions have been satisfied. This may be provided by the IBS 106 and/or may be provided using the method of FIG. 3.

At 501, the control module and/or LV drain detection module 127 is configured to determine whether one or more first trigger conditions are satisfied. As an example, the BCH flag may be checked. If yes, operation 502 may be performed, otherwise operation 504 may be performed.

At 502, the control module and/or the countermeasure module 149 performs a first one or more countermeasures. As an example, the back office 202 may generate an alert message and transmit the alert message to the vehicle 100, which may then provide the alert message to the driver and/or user of the vehicle 100. The alert message may indicate: the LV battery 108 has a parasitic drain; indicate that there is a slow parasitic drain on the LV battery 108; whether the LV battery 108 is being maintained; to schedule a visit to a dealer of the vehicle 100 and/or service station; a risk level regarding ability to start the vehicle 100; etc. The alert message may be generated at the vehicle 100 without receiving an alert message from the back office 202. Other countermeasures may be performed such as limiting loading on the LV battery 108.

At 504, the control module and/or LV drain detection module 127 is configured to determine whether one or more second trigger conditions are satisfied. As an example, the ASD flag and/or the SOC error flag may be checked. In an embodiment both of these flags are checked and if both of these flags are HIGH (or a 1), then operation 506 is performed, otherwise operation 508 may be performed.

At 506, the control module and/or the countermeasure module 149 performs a second one or more countermeasures. As an example, the back office 202 may send an alert message to the vehicle 100 and/or the vehicle 100 may generate an alert message indicating to the driver and/or user of the vehicle 100 to start the vehicle 100 as soon as possible. In an embodiment, the vehicle control module 104 may start the vehicle 100. This allows the vehicle 100 to charge the LV battery 108 via the HV battery pack 121 and to reset one or more electronic control units (ECUs) including resetting the vehicle control module 104. In doing so, an ECU (or processor) that is “stuck” (i.e., operating in an infinite loop) is reset and is no longer operating in an infinite loop. The alert message may indicate that the LV battery 108 has a high parasitic drain. Other countermeasures may be performed such as limiting loading on the LV battery 108.

At 508, the control module and/or LV drain detection module 127 is configured to determine whether one or more third trigger conditions are satisfied. As an example, the SOC flag and the low HV SOC flag are checked for the LV battery 108 and the HV battery pack 121. If yes, operation 510 may be performed, otherwise the method may end.

At 510, the control module and/or the countermeasure module 149 performs a third one or more countermeasures. As an example, the back office 202 may send an alert message to the vehicle 100 and/or the vehicle 100 may generate an alert message indicating to the driver and/or user of the vehicle 100 to start the vehicle 100 or to plug in the vehicle 100 to charge the LV battery 108 and/or the HV battery pack 121. The alert message may indicate the LV battery 108 has a low SOC and/or the HV battery pack 121 has a low SOC. The SOCs of the LV battery 108 and the HV battery pack 121 may be indicated. If the vehicle is already plugged in, the control module and/or the countermeasure module 149 may automatically begin charging the vehicle 100. Other countermeasures may be performed such as limiting loading on the LV battery 108.

The above-described operations of FIGS. 3-5 are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The examples disclosed herein include use of a cloud-based analytics approach throughout a vehicle life cycle. This includes checking for and detecting parasitic drains both onboard (locally) and offboard (remotely). The examples aid in preventing “walk-home” events by detecting and alerting vehicles of LV battery parasitic drains. The examples isolate which trigger conditions are satisfied and perform countermeasures to address the satisfied trigger conditions. This aids in isolating the LV parasitic drain and not simply focusing on the state of the LV battery.

LV parasitic drain detection can reduce replacement and warranty costs and improve customer satisfaction. The examples provide quick detection of the satisfied trigger conditions associated with one or more LV parasitic drains of a LV battery by proactively servicing the vehicle while the parasitic drain is present. The examples leverage data available in the vehicle. The examples allow for monitoring of vehicles of a certain model, make and/or type and/or vehicles of a fleet. This may be done during manufacturing and/or during use to determine whether the vehicles are exhibiting similar behavior and/or exhibiting similar issues. The collected battery data may be analyzed by algorithms at the vehicle, at a back office, at a dealer or service station, and at a manufacturing plant, and may be used by customers and/or manufacturers.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Per, Pascal, Curl, OCaml, Javascript®, HTMLS (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A drain detection system for a vehicle, the drain detection system comprising:
a sensor configured to detect a plurality of parameters of a low-voltage battery of the vehicle and collect battery data including the plurality of parameters when the vehicle is OFF;
a telematics module; and
a control module configured to i) receive the battery data from the sensor when the vehicle is ON, ii) transmit via the telematics module the battery data to a network device, which is remotely located from the vehicle, iii) receive an alert message from the network device indicative of a parasitic drain on the low-voltage battery, and iv) perform a first countermeasure in response to the alert message.

2. The drain detection system of claim 1, wherein the low-voltage battery is configured to close a contactor for a high-voltage battery pack or start an internal combustion engine.

3. The drain detection system of claim 1, wherein:
the battery data includes a state of charge of the low-voltage battery;
the state of charge is due to at least the parasitic drain; and
the alert message is generated based on the state of charge.

4. The drain detection system of claim 1, wherein:
the battery data includes a drain rate of the low-voltage battery;
the drain rate is due to at least the parasitic drain; and
the alert message is generated based on the drain rate.

5. The drain detection system of claim 1, wherein:
the battery data includes a current draw of the low-voltage battery;
the current draw is due to at least the parasitic drain; and
the alert message is generated based on the current draw.

6. The drain detection system of claim 1, wherein:
the battery data indicates a low state of charge of a high-voltage battery pack of the vehicle; and
the alert message is generated based on the low state of charge of the high-voltage battery pack.

7. A drain detection system for a vehicle, the drain detection system comprising:
a sensor configured to detect a plurality of parameters of a low-voltage battery of the vehicle and collect battery data including the plurality of parameters when the vehicle is OFF; and
a control module configured to i) receive the battery data from the sensor when the vehicle is ON, ii) based on the battery data, detect a parasitic drain on the low-voltage battery, and iii) perform a countermeasure in response to detecting the parasitic drain.

8. The drain detection system of claim 7, wherein the low-voltage battery is configured to close a contactor for a high-voltage battery pack or start an internal combustion engine.

9. The drain detection system of claim 7, wherein:
the battery data includes a state of charge of the low-voltage battery;
the state of charge is due to at least the parasitic drain; and
the countermeasure is performed based on the state of charge.

10. The drain detection system of claim 7, wherein:
the battery data includes a drain rate of the low-voltage battery;
the drain rate is due to at least the parasitic drain; and
the countermeasure is performed based on the drain rate.

11. The drain detection system of claim 7, wherein:
the battery data includes a current draw of the low-voltage battery;
the current draw is due to at least the parasitic drain; and
the countermeasure is performed based on the current draw.

12. The drain detection system of claim 7, wherein:
the battery data indicates a low state of charge of a high-voltage battery pack of the vehicle; and
the countermeasure is performed based on the low state of charge of the high-voltage battery pack.

13. A network device of a drain detection system for a first vehicle, the network device comprising:
a transceiver configured to receive battery data from the first vehicle, the battery data comprising a plurality of parameters of a low-voltage battery of the first vehicle, and being collected when the first vehicle is OFF and transmitted to the network device when the first vehicle is ON; and
a control module configured to detect a parasitic drain on the low-voltage battery based on the battery data, and in response to detecting the parasitic drain, transmit an alert message to the first vehicle indicative of the parasitic drain and to cause the first vehicle to perform a first countermeasure due to existence of the parasitic drain.

14. The network device of claim 13, wherein the transceiver is configured to receive battery data from a plurality of vehicles including the first vehicle, and transmit a second alert message to a second vehicle based on the battery data collected at the first vehicle.

15. The network device of claim 13, wherein:
the battery data indicates at least one of a state of charge of the low-voltage battery, a drain rate of the low-voltage battery, a current draw from the low-voltage battery, and a low state of charge of a high-voltage battery pack of the first vehicle; and
the control module is configured to perform the first countermeasure based on the at least one of the state of charge of the low-voltage battery, the drain rate of the low-voltage battery, the current draw from the low-voltage battery, and the low state of charge of the high-voltage battery pack.

16. The network device of claim 13, wherein:
the battery data indicates a state of charge of the low-voltage battery, a drain rate of the low-voltage battery, a current draw from the low-voltage battery, and a low state of charge of a high-voltage battery pack of the first vehicle; and
the control module is configured to perform the first countermeasure based on the state of charge of the low-voltage battery, the drain rate of the low-voltage battery, the current draw from the low-voltage battery, and the low state of charge of the high-voltage battery pack.

17. The network device of claim 13, wherein the control module is configured to:
based on the battery data, determine that a first trigger condition is satisfied, which is indicative of existence of the parasitic drain; and
in response to determining existence of the first trigger condition, perform the first countermeasure.

18. The network device of claim 17, wherein the control module is configured to:
based on the battery data, determine that a second trigger condition is satisfied, which is indicative of existence of the parasitic drain, the second trigger condition being different than the first trigger condition; and
in response to determining existence of the second trigger condition, perform a second countermeasure, the second countermeasure being different than the first countermeasure.

19. The network device of claim 18, wherein the control module is configured to:
based on the battery data, determine that a third trigger condition is satisfied, which is indicative of existence of the parasitic drain, the third trigger condition being different than the first trigger condition and the second trigger condition; and
in response to determining existence of the third trigger condition, perform a third countermeasure, the third countermeasure being different than the first countermeasure and the second countermeasure.

20. The network device of claim 13, wherein the control module is configured, based on the battery data, to determine that a first trigger condition and a second trigger condition are satisfied, which are indicative of the parasitic drain, and in response to determining existence of the first trigger condition and the second trigger condition, perform the first countermeasure.
